(19) United States
(12) Patent Application Publication
(10) Pub. No.: US 2008/0317253 A1
(43) Pub. Date: Dec. 25, 2008

(54) Audio processing systems

(75) Inventor: Wei-Cheng Lin, Taipei County (TW)

Correspondence Address: Joe McKinney Muncy, PO Box 1364, Fairfax, VA, 22038-1364, US

(73) Assignee: PRINCETON TECHNOLOGY CORPORATION

(21) Appl. No.: 11/892,109

(22) Filed: Aug. 20, 2007

(30) Foreign Application Priority Data
Jun. 23, 2007 (TW) 096122716

(51) Int. Cl. H03G 3/00

(52) U.S. Cl. 381/63

(57) ABSTRACT

An audio processing system comprising processing devices and a processing module. The processing devices generate output signals, and the processing module calculates the output signals from the processing devices and generates an output result signal. Each processing device comprises a control module, a timing generation module, a memory module, and a conversion module. The control module receives an input control signal and generates a first control signal and a second control signal. The timing generation module is coupled to the control module and generates a timing signal according to the second control signal. The memory module is coupled to the control module and the timing generation module. The memory module receives and stores an audio signal and generates a memory signal according to the first control signal and the timing signal. The conversion module is coupled to the memory module and converts the memory signal to the output signal.

### BACKGROUND OF THE INVENTION

1. Field of the Invention

The invention relates to a processing systems, and more particularly to an audio processing system for enhancing echo effect.

2. Description of the Related Art

With the advancement of technology and success of businesses, music is an important part of everyday life, and modern people often enjoy music during their leisure time. A soft melody can mitigate the pressures of life and improve emotional-state among other positive factors. Different audio products and output qualities are provided according to different requirements.

In a conventional digital audio processor, the operation for generating echo is performed by an analog-to-digital converter. The analog-to-digital converter converts an input analog signal to a digital signal and stores the digital signal in a memory which can be accessed randomly. Data of the stored digital signal is read from the memory to serve as another digital signal. A digital-to-analog converter converts the read digital signal to an analog signal for outputting. Thus, the input analog signal is delayed. The analog signal for outputting is fed back and combined with normal input analog signals, and then the combined analog signals are transmitted to the analog-to-digital converter. Moreover, the analog signal for outputting is transmitted to an output amplifier. The analog signal for outputting is amplified to drive speakers. Voice with echo is accordingly generated.

Due to surrounding environment factors, echo effect generated by a one-staged digital audio processor does not satisfy consumers whom request high quality music sound. Thus, it is desired to provide an audio processor which can enhance the quality of echo effect generated from an audio signal and prevent the echo effect from being influenced by surrounding environment factors.

### BRIEF SUMMARY OF THE INVENTION

An audio processing system generating echo effect which is not influenced by surrounding environment factors is provided.

An exemplary embodiment of an audio processing system comprises a plurality of processing devices and a processing module. The processing devices generate a plurality of output signals, and the processing module calculates the output signals from the processing devices and generates an output result signal. Each processing device comprises a control module, a timing generation module, a memory module, and a conversion module. The control module receives an input control signal and generates a first control signal and a second control signal. The timing generation module is coupled to the control module and generates a timing signal according to the second control signal. The memory module is coupled to the control module and the timing generation module. The memory module receives and stores an audio signal and generates a memory signal according to the first control signal and the timing signal. The conversion module is coupled to the memory module and converts the memory signal to the output signal.

A detailed description is given in the following embodiments with reference to the accompanying drawings.

### BRIEF DESCRIPTION OF THE DRAWINGS

The invention can be more fully understood by reading the subsequent detailed description and examples with references made to the accompanying drawings, wherein:

FIG. 1 shows an exemplary embodiment of an audio processing system;

FIG. 2 shows an exemplary embodiment of a processing device of an audio processing system; and

FIG. 3 shows another exemplary embodiment of an audio processing system.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

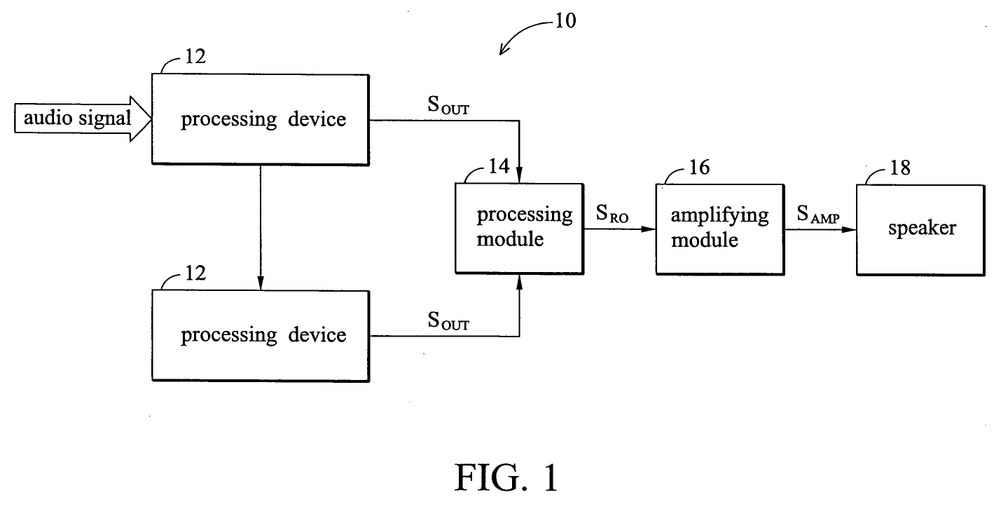

Audio processing systems are provided. Referring to FIG. 1, in an exemplary embodiment of an audio processing system, an audio processing system 10 comprises a plurality of processing devices 12 and a processing module 14. The processing devices 12 generate a plurality of output signals S_{OUT}. The processing module 14 calculates the output signals S_{OUT} from the processing devices 12 to generate an output result signal S_{RO}. In some embodiments, the processing module 14 is a multiplier and calculates the output signal S_{OUT} by multiplication to generate the output result signal S_{RO}. The audio processing system 10 further comprises an amplifying module 16 and a speaker 18. The amplifying module 16 is coupled to the processing module 14 and amplifies the output result signal S_{RO} to generate an amplified signal S_{AMP}. The speaker 18 is coupled to the amplifying module 16 and broadcasts according to the amplified signal S_{AMP}.

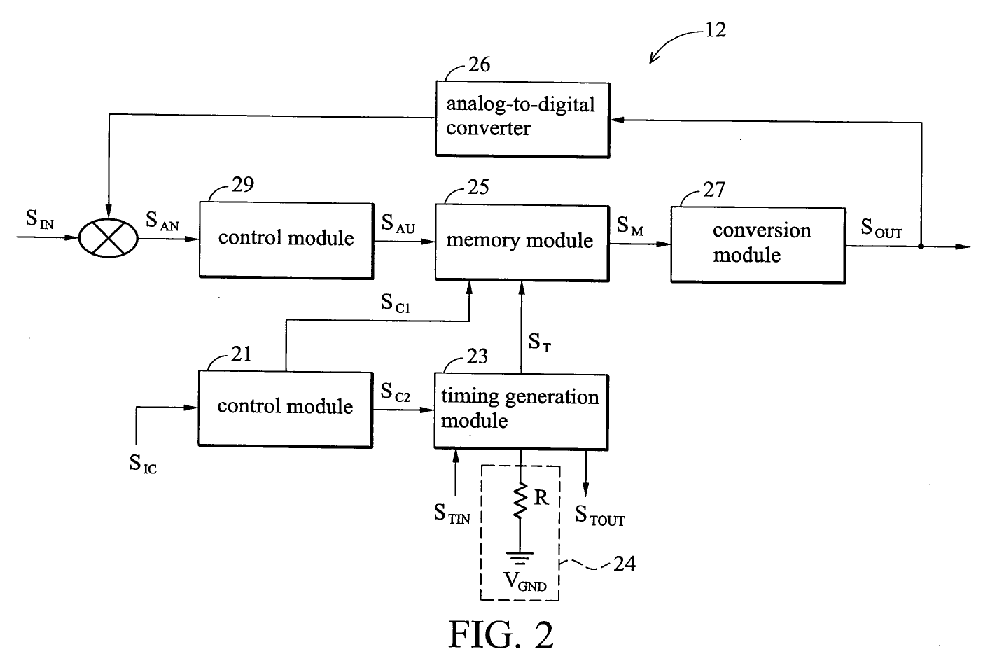

FIG. 2 shows an exemplary embodiment of the processing device 12 of the audio processing system 10 in FIG. 1. Referring to FIGS. 1 and 2, each of the processing devices 12 of the audio processing system 10 comprises a control module 21, a timing generation module 23, a memory module 25, and a conversion module 27. The control module 21 receives an input control signal S_{IC} and generates a first control signal S_{C1} and a second control signal S_{C2}. The timing generation module 23 is coupled to the control module 21 and generates a timing signal S_{T} according to the second control signal S_{C2}. The memory module 25 is coupled to the control module 21 and the timing generation module 23 and receives and stores an audio signal S_{AU}. The memory module 25 generates a memory signal S_{M} according to the first control signal S_{C1} and the timing signal S_{T}. The conversion module 27 is coupled to the memory module 25 and transforms the memory signal S_{M} to the output signal S_{OUT}. In some embodiments, the conversion module 27 is implemented by a digital-to-analog converter and converts the memory signal S_{M} to the output signal S_{OUT} with analog form.

The processing device 12 further comprises an analog-to-digital converter 29 coupled to the memory module 25. The analog-to-digital converter 29 converts an analog signal S_{AN} to the audio signal S_{AU} with digital form. The analog signal S_{AN} is obtained by combining an input signal S_{IN} and the output signal S_{OUT}. The processing device 12 further comprises a filter 26 coupled between the conversion module 27 and the analog-to-digital converter 29. The filter 26 filters the output signal S_{OUT} and outputs the filtered output signal S_{OUT} for combining with the input signal S_{IN} to generate the analog signal S_{AN}.

The timing generation module 23 comprises a timing adjustment unit 24 for adjusting the magnitude of the timing signal S_{T}. In some embodiments, the timing adjustment unit 24 is implemented by a variable resistor R coupled to a ground V_{GND}. According to requirements, the timing signal S_{T} with a different clock is generated by adjusting the resistance of the variable resistor R. The timing generation module 23 further receives a timing input signal S_{TIN} from an external device. The timing generation module 23 generates a corresponding timing output signal S_{TOUT} according to the received timing input signal S_{TIN}.

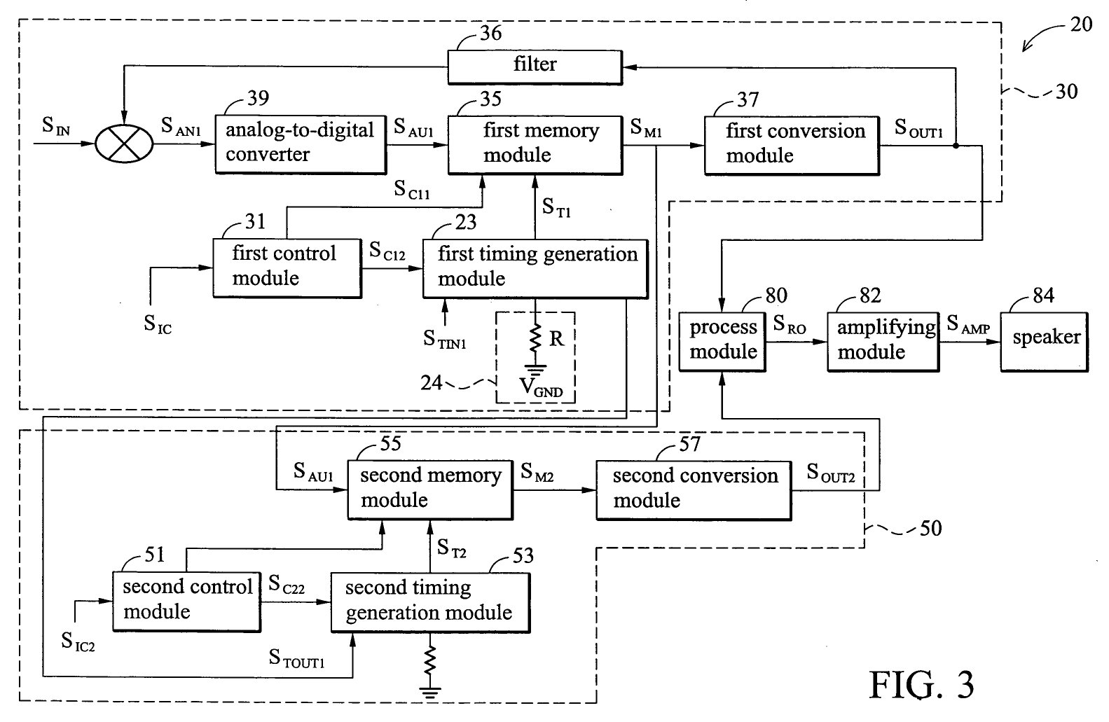

FIG. 3 shows another exemplary embodiment of an audio processing system comprising a plurality of processing devices. Referring to FIG. 3, to describe the operation of an audio processing system 20, two processing devices, first processing device 30 and second processing device 50, are given as an example. The first processing device 30 comprises a first control module 31, a first timing generation module 33, a first memory module 35, and a first conversion module 37. The first control module 31 receives a first input control signal S_{IC1} and generates a first control signal S_{C11} and a second control signal S_{C12}. The first timing generation module 33 is coupled to the first control module 31 and generates a first timing signal S_{T1} according to the second control signal S_{C12}. The first memory module 35 is coupled to the first control module 31 and the first timing generation module 33 and receives and stores a first audio signal S_{AU1}. The first memory module 35 generates a first memory signal S_{M1} according to the first control signal S_{C11} and the first timing signal S_{T1}. The first conversion module 37 is coupled to the first memory module 35 and converts the first memory signal S_{M1} to a first output signal S_{OUT1}.

The second processing device 50 comprises a second control module 51, a second timing generation module 53, a second memory module 55, and a second conversion module 57. The second control module 51 receives a second input control signal S_{IC2} and generates a first control signal S_{C21}, and a second control signal S_{C22}. The second timing generation module 53 is coupled to the second control module 51 and the first timing generation module 33 of the first processing device 30. The second timing generation module 53 generates a second timing signal S_{T2} according to the second control signal S_{C22} and the first timing output signal S_{TOUT1} from the first timing generation module 33. The second memory module 55 is coupled to the second control module 51, the second timing generation module 53, and the first memory module 35. The second memory module 55 receives and stores the first memory signal S_{M1} from the first memory module 35. The second memory module 55 generates a second memory signal S_{M2} according to the first control signal S_{C21} and the second timing signal S_{T2}. The second conversion module 57 is coupled to the second memory module 55 and converts the second memory signal S_{M2} to a second output signal S_{OUT2}.

In this embodiment, the first input control signal S_{IC1} received by the first control module 31 is used to couple the first control module 31 to a ground, in other words, the first input control signal S_{C11} is at a low logic level. On the contrary, the second input control signal S_{IC2} received by the second first control module 51 is at a high logic level. The audio processing system 20 generates the first output signal S_{OUT1} and the second output signal S_{OUT2} according to the above operations performed by the first processing device 30 and the second processing device 50. Then, a processing module 80 combines the first output signal S_{OUT1} and the second output signal S_{OUT2} to generate an output result signal S_{RO}. An amplifying module 82 amplifies the output result signal S_{RO} to generate an amplified signal S_{AMP}. A speaker 84 broadcasts according to the amplified signal S_{AMP}. The operation of the audio processing system 20 is achieved to generate echo effect which is not influenced by surrounding environment factors.

According to an audio processing system of the above embodiments, a plurality of cascading processing devices respectively generate a plurality of output signals, and then the output signals are combined to generate an output result signal. After the output result signal is amplified by an amplifying module, a speaker broadcasts according to the amplified signal. Thus, undesired echo effect generated by a single audio processor can be overcome. An audio processing system of the above embodiments can mitigate the negative effect of surrounding environment factors and enhance quality of echo effect.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. An audio processing system, comprising
a plurality of processing devices generating a plurality of output signals, wherein each processing device comprises:
a control module for receiving an input control signal and generating a first control signal and a second control signal;
a timing generation module, coupled to the control module, for generating a timing signal according to the second control signal;
a memory module, coupled to the control module and the timing generation module, for receiving and storing an audio signal and generating a memory signal according to the first control signal and the timing signal; and
a conversion module, coupled to the memory module, for converting the memory signal to the output signal; and
a processing module for calculating the output signals from the processing devices and generating an output result signal.

2. The audio processing system as claimed in claim 1, wherein each of the processing devices further comprises an analog-to-digital converter, coupled to the memory module, for converting an analog signal to the audio signal with a digital form.

3. The audio processing system as claimed in claim 2, wherein the analog signal is obtained by combining an input signal and the output signal.

4. The audio processing system as claimed in claim 3, wherein each of the processing devices further comprises a filter, coupled to the conversion module and the analog-to-digital converter, for filtering the output signal.

5. The audio processing system as claimed in claim 4, wherein the conversion module is a digital-to-analog converter for converting the memory signal to the output signal with an analog form.

6. The audio processing system as claimed in claim 1, wherein the timing generation module comprises a timing adjustment unit for adjusting a magnitude of the timing signal.

7. The audio processing system as claimed in claim 6, wherein the timing adjustment unit is a variable resistor, and the timing generation module generates the timing signal with different clock adjusting a resistance of the variable resistor.

8. The audio processing system as claimed in claim 1, wherein the timing generation module generates a timing output signal according to a timing input signal.

9. The audio processing system as claimed in claim 1, wherein the processing module is a multiplier and calculates the output signals by multiplication to generate the output result signal.

10. The audio processing system as claimed in claim 9 further comprising:
an amplifying module, coupled to the processing module, for amplifying the output result signal to generate an amplified signal; and
a speaker, coupled to the amplifying module, for broadcasts according to the amplified signal.

11. The audio processing system as claimed in claim 1, wherein the processing devices comprises a first processing device and a second processing device, and a second memory module of the second processing device is coupled to a first memory module of the first processing device, and a second audio signal received by the second memory module is a first memory signal generated by the first memory module.

12. The audio processing system as claimed in claim 11, wherein a second timing generation module of the second processing device is coupled to a first timing generation module of the first processing device, and the second timing generation module receives a timing output signal generated by the first timing generation and generates the timing signal.

13. The audio processing system as claimed in claim 11, wherein a first input control signal received by the first processing module is used to coupled the first processing module to a ground.

14. The audio processing system as claimed in claim 13, wherein the first input control signal received by the first processing module is a low logic level.

15. The audio processing system as claimed in claim 14, wherein a second input control signal received by the second processing module is at a high logic level.

16. The audio processing system as claimed in claim 12, wherein a second timing input signal received by the second timing generation module of the second processing module is a first timing output signal generated by the first timing generation of the first processing module.
